(19) United States
(12) Patent Application Publication
(10) Pub. No.: US 2015/0130454 A1
(43) Pub. Date: May 14, 2015

(54) DAMAGE DETECTING APPARATUS

(71) Applicant: TOKYO ROPE MFG. CO., LTD., Tokyo (JP)

(72) Inventors: Hiroaki ITOI, Kasumigaura-shi (JP); Takashi FUSEDA, Tokyo (JP)

(73) Assignee: TOKYO ROPE MFG. CO., LTD., Tokyo (JP)

(21) Appl. No.: 14/605,566

(22) Filed: Jan. 26, 2015

Related U.S. Application Data
(63) Continuation of application No. PCT/JP2012/076698, filed on Oct. 16, 2012.

(30) Foreign Application Priority Data
Jul. 27, 2012 (JP) 2012-167799

(51) Int. Cl. G01N 27/82; G01R 1/18

(52) U.S. Cl. CPC G01N 27/82; G01R 1/18
USPC 324/240

(57) ABSTRACT

A damage detecting apparatus comprises a magnetic-flux generating unit, a first magnetic-flux detecting element, a second magnetic-flux detecting element and a supporting unit. The magnetic-flux generating unit generates a magnetic flux in an object to be inspected. The first magnetic-flux detecting element is detects a magnetic flux leaking from a circumferential part of the object. The second magnetic-flux detecting element is arranged, opposing the first magnetic-flux detecting element across the object and detects a magnetic flux leaking from any other circumferential part of the object. The supporting unit supports the first and second magnetic-flux detecting elements, enabling the first and second magnetic-flux detecting elements to change in position relative to each other in a diameter direction of the object.

### CROSS-REFERENCE TO RELATED APPLICATIONS

This is a Continuation application of PCT application No. PCT/JP/2012/076698, filed Oct. 16, 2012, which was published under PCT Article 21(2) in Japanese.

This application is based upon and claims the benefit of priority from prior Japanese Patent Application No. 2012-167799, filed Jul. 27, 2012, the entire contents of which are incorporated herein by reference.

### BACKGROUND OF THE INVENTION

1. Field of the Invention

This invention relates to a damage detecting apparatus for detecting damaged parts of an object such as a wire rope.

2. Description of the Related Art

Wire ropes for use in elevators, lifts, cranes, etc., are composed of strands, each made by twisting, for example, a plurality of steel wires. All wire rope degrades after extended use, and some wires break or wear. Wire rope is thus inspected at regular intervals in order to detect any damaged parts.

An apparatus for inspecting wire ropes has been proposed, which uses the so-called “magnetic-flux leakage method,” by which the magnetic fluxes leaking from the damaged parts of a wire rope are detected. The wire-rope inspecting apparatus has a magnetic-flux generating means and a magnetic-flux detecting means. The magnetic-flux generating means magnetizes the wire rope in the lengthwise direction. If some parts of the wire rope are damaged, magnetic fluxes will leak from such parts. The leaking magnetic fluxes are detected by the magnetic-flux detecting means. The damaged parts are thereby detected. (Refer to, for example, Patent Documents 1 and 2 identified below.)

### PRIOR-ART DOCUMENTS

Patent Document 1: Jpn. Pat. Appin. KOKAI Publication 2010-8213

Patent Document 2: Jpn. Pat. Appin. KOKAI Publication 2007-205816

### BRIEF SUMMARY OF THE INVENTION

Wire ropes of various diameters are available. Any wire rope inspecting apparatus that detects the magnetic fluxes leaking from a wire rope has a magnetic-flux generating means and a magnetic-flux detecting means, both designed to inspect wire ropes having a particular diameter. In other words, the wire rope inspecting apparatus must be changed in configuration in accordance with the diameter of the wire rope it should inspect. Before the use of the apparatus, therefore, much labor is inevitably required to achieve the configuration change.

Accordingly, an object of this invention is to provide a damage detecting apparatus that can be used to detect the damaged parts of objects having different diameters.

A damage detecting apparatus comprising:

a magnetic-flux generating unit configured to generate a magnetic flux in an object to be inspected, the object having magnetic flux;

a first magnetic-flux detecting element configured to detect a magnetic flux leaking from a circumferential part of the object;

a second magnetic-flux detecting element arranged, opposing the first magnetic-flux detecting element across the object, and configured to detect a magnetic flux leaking from any other circumferential part of the object; and

a supporting unit configured to support the first and second magnetic-flux detecting elements, enabling the first and second magnetic-flux detecting elements to change in position relative to each other in a diameter direction of the object.

This invention can provide a damage detecting apparatus that can detect the damaged parts of objects having different diameters.

### BRIEF DESCRIPTION OF THE SEVERAL VIEWS OF THE DRAWINGS

The accompanying drawings, which are incorporated in and constitute a part of the specification, illustrate embodiments of the invention, and together with the general description given above and the detailed description of the embodiments given below, serve to explain the principles of the invention.

FIG. 1 is a schematic diagram showing a wire-rope damage detecting system that has a damage detecting apparatus according to an embodiment of this invention;

FIG. 2 is a sectional view of the wire-rope damage detecting apparatus shown in FIG. 1, taken along line F2-F2 shown in FIG. 1;

FIG. 3 is a schematic diagram showing the first and second case members of the wire-rope damage detecting apparatus, which have been rotated relative to each other around hinge axles;

FIG. 4 is a schematic diagram showing the wire-rope damage detecting apparatus;

FIG. 5 is a schematic diagram showing the wire-rope damage detecting apparatus;

FIG. 6 is schematic a diagram showing the wire-rope damage detecting apparatus;

FIG. 7 is a diagram showing a wire rope held in the first and second holding grooves of the first and second cases, while both cases remain closed;

FIG. 8 is a schematic diagram showing the first and second substrates as viewed in a first direction, while the wire rope remains held in the first and second holding grooves;

FIG. 9 is a schematic diagram showing the first and second substrates as viewed in the first direction, while the wire rope remains held in the first and second holding grooves;

FIG. 10 is a schematic diagram showing the first and second substrates as viewed in the first direction, while the wire rope remains held in the first and second holding grooves;

FIG. 11 is a schematic diagram showing the first and second substrates as viewed in the first direction, while the wire rope remains held in the first and second holding grooves;

FIG. 12 is a block diagram showing the signal processing device and alarm device, both incorporated in the wire-rope damage detecting system; and

FIG. 13 is an equivalent circuit diagram of the GMR element used in both the first and second magnetic-flux detecting elements incorporated in the wire-rope damage detecting apparatus.

### DETAILED DESCRIPTION OF THE INVENTION

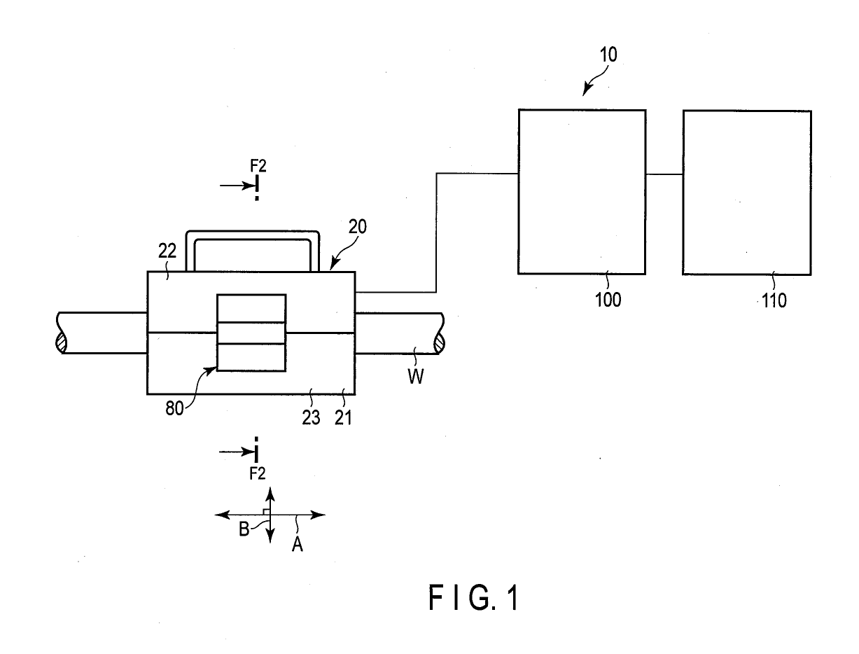

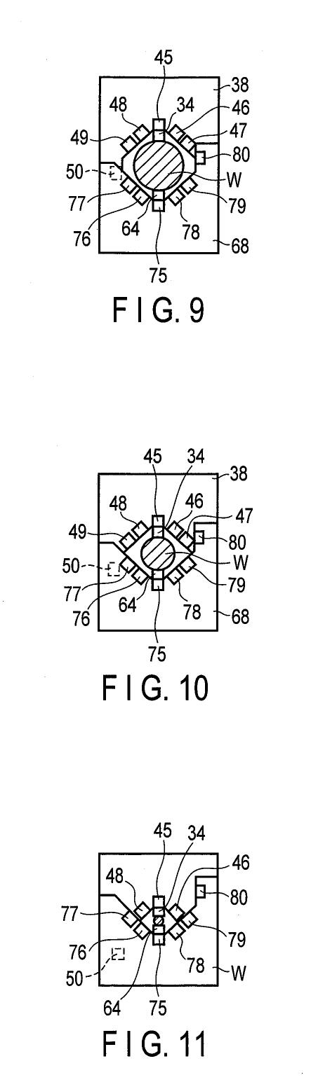

A damage detecting apparatus according to an embodiment of this invention will be described with reference to FIG. 1 to FIG. 13. FIG. 1 is a schematic diagram showing a wire-rope damage detecting system 10 that comprises a wire-rope damage detecting apparatus 20 according to the embodiment of this invention. As FIG. 1 shows, the wire-rope damage detecting system 10 comprises the wire-rope damage detecting apparatus 20, a signal processing device 100, and an alarm device 110. The wire-rope damage detecting apparatus 20 comprises a case 21 and products contained in the case 21. The product will be described later in detail.

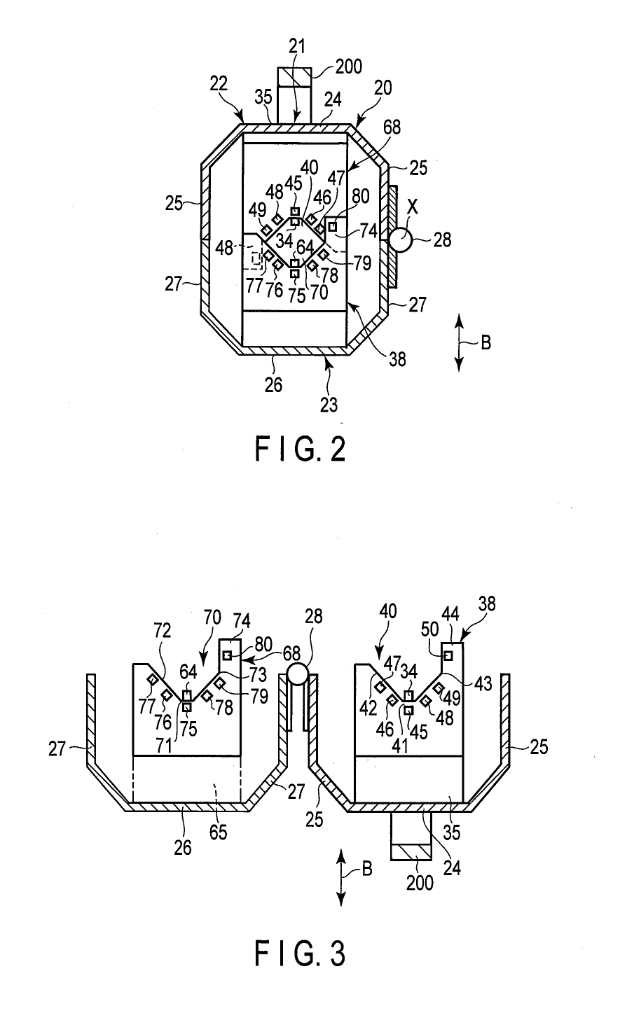

FIG. 2 is a sectional view of the wire-rope damage detecting apparatus 20, taken along line F2-F2 shown in FIG. 1. More specifically, FIG. 2 is a sectional view taken at a middle part in the lengthwise direction, along a line perpendicular to the lengthwise direction. As seen from FIGS. 1 and 2, the case 21 is shaped like a hollow cylinder and comprises a first case member 22 and a second case member 23. The first case member 22 comprises a first bottom wall part 24 and a pair of first sidewall parts 25. The first sidewall parts 25 extend from the two edges of the first bottom wall part 24, respectively. Having the first bottom wall part 24 and the pair of first sidewall parts 25, the first case member 22 is concave as shown in FIG. 2.

A handle 200 is secured to the first bottom wall part 24. The handle 200 is the member the operator holds when he or she uses the wire-rope damage detecting apparatus 20.

The second case member 23 has the same shape as the first case member 22, and comprises a second bottom wall part 26 and a pair of second sidewall parts 27. The second sidewall parts 27 extend from the two edges of the second bottom wall part 26, respectively.

The first case member 22 and the second case member 23 are coupled to each other by a hinge device 28. FIG. 2 shows the first and second case members 22 and 23 coupled together, defining a storage space in the case 21. In the state shown in FIG. 2, the case 21 remains closed.

The hinge device 28 couples one first sidewall part 25 and one second sidewall part 27 together. The hinge device 28 has a hinge axle X, which extends in the lengthwise direction of the case 21. The first case member 22 and the second case member 23 can therefore rotate relative to each other around the hinge axle X. FIG. 3 shows the first and second case members 22 and 23 rotated relative to each other, around the hinge axle X. In this state, the first and second case members 22 and 23 remain opened.

The orientation of the wire-rope damage detecting apparatus 20 will be defined. The first direction A is the lengthwise direction of the case 21. The second direction B is the direction from the first bottom wall part 24 to the second bottom wall part 26 coupled together, closing the case 21. In other words, the second direction B is the direction from the first bottom wall part 24 to the second bottom wall part 26 and also from the second bottom wall part 26 to the first bottom wall part 24, while the case 21 remains closed as shown in FIG. 2. The first direction A and the second direction B cross each other at right angles.

The product contained in the case 21, the position of which is shown in FIG. 2, will be described in detail, assuming that the case 21 is closed. In other words, the product will be described with respect to the posture it takes as shown in FIG. 2.

The product comprises a first part 30 and a second part 60. The first part 30 is secured in the first case member 22. The second part 60 is secured in the second case member 23.

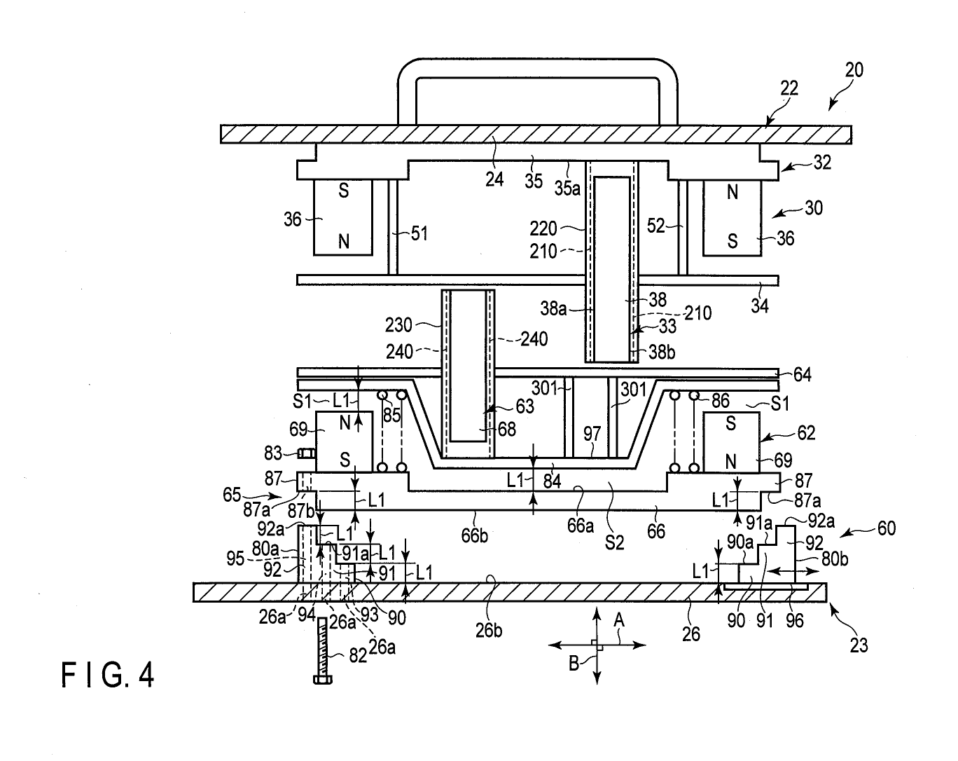

FIG. 4 is a schematic diagram showing the wire-rope damage detecting apparatus 20. As shown in FIG. 4, the first part 30 comprises a first magnetic-flux generating part 32, a first magnetic-flux detecting part 33, and a first guard member 34.

The first magnetic-flux generating part 32 comprises a first yoke 35 and a pair of first magnet members 36. The first yoke 35 is made of a ferromagnetic material. The first yoke 35 is shaped like a plate and extends in one direction. The first yoke 35 is secured to the first bottom wall part 24 of the first case member 22 and extends lengthwise along the first case member 22. The first yoke 35 may be secured to the first bottom wall part 24, with bolts and nuts or with adhesive.

The first magnet members 36, paired with each other, are permanent magnets, and are fastened to the inner surface 35a of the first yoke 35. The inner surface 35a faces the inner surface of the case 21, and is a plane perpendicular to the second direction B. The first magnet members 36 are spaced apart from each other in the first direction A. The first magnet members 36 are secured to the first yoke 35, each with its magnetic poles facing, at an inner surface, the inner surface of the opposite-polarity poles of the other first magnet member 36.

More precisely, one first magnet member 36 has its S pole secured to the first yoke 35 and its N pole facing inwards, and the other first magnet member 36 has its N pole secured to the first yoke 35 and its S pole facing inwards.

The first magnetic-flux detecting part 33 comprises a first substrate storage case 220, a first substrate 38, a plurality of first magnetic-flux detecting elements, and a first magnetism-shielding member 210. The first substrate 38 is secured without being displaced with respect to the first case member 22. In the embodiment, the first substrate 38 is secured to the first yoke 35 by, for example the first substrate storage case 220.

FIG. 3 is a sectional view of the wire-rope damage detecting apparatus 20, illustrating the first and second case members 22 and 23 and showing the first substrate 38 as seen from the outside. As may be seen from FIG. 3, the first substrate 38 protrudes from the first yoke 35 in the second direction B. The first substrate 38 is, for example, a plate-shaped member. The first substrate 38 is held in the first substrate storage case 220, with both surfaces 38a and 38b extending perpendicular to the lengthwise direction of the first yoke 35. The first substrate 38 is secured to the first yoke 35 by the first substrate storage case 220.

The distal end of the first substrate 38 has a first holding groove 40. The first holding groove 40 is configured to hold a wire rope W. The first holding groove 40 is V-shaped as viewed from above. The first holding groove 40 has a bottom surface 41, a first sloping surface 42, a second sloping surface 43, and a projecting part 44, and penetrates the first substrate 38.

The bottom surface 41 is located in the middle, in a widthwise direction, of the first substrate 38. The bottom surface 41 is flat. The first sloping surface 42 extends from one end of the bottom surface 41 to the distal end of the first substrate 38. The second sloping surface 43 extends from the other end of the bottom surface 41 to the distal end of the first substrate 38. The first and second sloping surfaces 42 and 43 are flat. Therefore, the first holding groove 40 is shaped like the letter V as shown in FIG. 3, as viewed from above, the letter V being defined by the bottom surface 41 and the first and second sloping surfaces 42 and 43. In the first holding groove 40, the projecting part 44 protrudes in the second direction B from the second sloping surface at the distal end of the first substrate 38.

The first magnetic-flux detecting elements are giant magneto-resistive (GMR) elements. In this embodiment, a plurality of the first magnetic-flux detecting elements is provided. The six first magnetic-flux detecting elements 45 to 50 are provided, for example. The first magnetic-flux detecting elements 45 to 50 are identical, and each can be adjusted in terms of flux-detecting sensitivity.

The first magnetic-flux detecting elements 45 to 50 are fixed to the first substrate 38, at the edges of the first holding groove 40. The first magnetic-flux detecting element 45 is secured near the bottom surface 41. The first magnetic-flux detecting elements 46 and 47 are secured near the second sloping surface 42. The first magnetic-flux detecting elements 48 and 49 are secured near the second sloping surface 43. The first magnetic-flux detecting element 50 is secured near the projecting part 44.

As may be seen from FIG. 1, the result of detection performed by the first magnetic-flux detecting elements 45 to 50 is transmitted to the signal processing device 100.

The first magnetism-shielding member 210 covers the first substrate 38 and all first magnetic-flux detecting elements 45 to 50. The first magnetism-shielding member 210 has the function of controlling the first magnetic-flux detecting elements 45 to 50, inhibiting the elements 45 to 50 from detecting the magnetic fluxes leaking from any parts of the wire rope W, other than the damaged parts. In other words, the first magnetism-shielding member 210 reduces the influence of the magnetic fluxes leaking from any parts of the wire rope W other than the damaged parts.

The first magnetism-shielding member 210 is made of a material having high magnetic permeability and small coercive force. The member 210 is made of, for example, PB permalloy or PC permalloy, which is a nickel-iron alloy containing 35 to 80% nickel.

The first substrate 38 covered with the first magnetism-shielding member 210 is held in the first substrate storage case 220. The first substrate storage case 220 is made of a non-magnetic material. The first substrate storage case 220 opens at the distal end. That is, its distal end opens to the first holding groove 40 in the first direction A. Thus, the first substrate storage case 220 does not prevent the wire rope W from being held in the first holding groove 40.

FIGS. 2 and 3 illustrate neither the first magnetism-shielding member 210 nor the first substrate storage case 220, thereby showing the first substrate 38 and first magnetic-flux detecting elements 45 to 50 more conspicuously than otherwise.

The first guard member 34 is provided in the first holding groove 40, is fixed and faces the first bottom surface 41. The first guard member 34 is shaped like, for example, a rod, and is long in the first direction A, covering both first magnet members 36. The first guard member 34 is secured to the first case member 22. In this embodiment, the first guard member 34 is fastened to the first yoke 35 by, for example, fastening members 51 and 52.

The first guard member 34 prevents the wire rope W from directly contacting the first magnet members 36 and inner surface of the first holding groove 40 when wire rope W is placed in the first holding groove 40. More specifically, the wire rope W contacts the first guard member 34, and does not directly contact the first magnet members 36 or the inner surface of the first holding groove 40.

The second part 60 comprises a second magnetic-flux generating part 62, a second magnetic-flux detecting part 63, a second guard member 64, and a position adjusting device 65.

The second magnetic-flux generating part 62 comprises a second yoke 66 and a pair of second magnetic members 69. The second yoke 66 is made of a ferromagnetic material. The second yoke 66 is shaped like a plate and extends in one direction. The second yoke 66 is secured to the second case member 23. In the embodiment, the second yoke 66 is secured to the second bottom wall part 26 by the position adjusting device 65 (later described), and therefore lengthwise extends in the direction A.

Both second magnet members 6 are permanent magnets, and are fastened to the inner surface 66a of the second yoke 66. The inner surface 66a faces the inner surface of the second case member 23, and is a plane perpendicular to the second direction B. The second magnet members 69 are spaced part from each other in the first direction A. The second magnet members 69 are secured to the second yoke 66, each with its magnetic poles facing, at an inner surface, the inner surface of the opposite-polarity poles of the other first magnet member 69. More precisely, one second magnet member 69 has its S pole secured to the second yoke 66 and its N pole facing inwards, and the other second magnet member 69 has its N pole secured to the second yoke 66 and its S pole facing inwards.

The second magnetic-flux detecting part 63 comprises a second substrate storage case 230, a second substrate 68, a plurality of second detecting elements, and a second magnetism-shielding member 240. The second substrate 68 is secured to the position adjusting device 65 (described later) by the second substrate storage case 230. In FIG. 3, the two-dot dashed lines indicate the contour of the position adjusting device 65. The second substrate 68 protrudes inwards from the second yoke 66 in the second direction B. The second substrate 68 is, for example, a plate-shaped member. The second substrate 68 is held in the second substrate storage case 230, has both surfaces extending perpendicular to the first direction A, and is secured to the position adjusting device 65 by the second substrate storage case 230.

The distal end of the second substrate 68 has a second holding groove 70. The second holding groove 70 is configured to hold a wire rope W. The second holding groove 70 has the same shape as the first holding groove 40, i.e., V-shaped as viewed from above in the first direction A. The second holding groove 70 has a second bottom surface 71, a pair of second sloping surfaces 72, and a second projecting part 74.

The second bottom surface 71 is located at the middle, in the widthwise direction, of the second substrate 68. The bottom surface 71 is flat, perpendicular to the second direction B. The second sloping surfaces 72 extend from one end of the bottom surface 71 to the distal end of the second substrate 68. Both second sloping surfaces 72 are flat, parallel to the first direction A. Therefore, as shown in FIG. 3, the second holding groove 70 is shaped like the letter V defined by the straight edges of the second bottom surface 71 and both second sloping surfaces 72. In the second holding groove 70, the second projecting part 74 extends in the second direction B from the part of the distal opening edge of one second sloping surface 72. The first projecting part 44 and the second projecting part 74 are positioned opposed to each other.

The second magnetic-flux detecting elements are giant magneto-resistive (GMR) elements. In this embodiment, a plurality of second magnetic-flux detecting elements is provided. The six second magnetic-flux detecting elements 75 to 80 are provided, for example. The second magnetic-flux detecting elements 75 to 80 can be adjusted in terms of flux-detecting sensitivity.

The second magnetic-flux detecting elements 75 to 80 are fixed at the edges of the second holding groove 70. The second magnetic-flux detecting element 75 is secured near the second bottom surface 71. The second magnetic-flux detecting elements 76 and 77 are secured near one of the second sloping surfaces 73. The second magnetic-flux detecting elements 78 and 79 are secured near the other second sloping surface 72. The second magnetic-flux detecting element 80 is secured to the second projecting part 74.

The second magnetism-shielding member 240 covers the second substrate 68 and all second magnetic-flux detecting elements 75 to 80. The second magnetism-shielding member 240 has the function of controlling the second magnetic-flux detecting elements 75 to 80, inhibiting the elements 75 to 80 from detecting the magnetic fluxes leaking from any parts of the wire rope W other than the damaged parts. In other words, the second magnetism-shielding member 240 reduces the influence of the magnetic fluxes leaking from any parts of the wire rope W other than the damaged parts.

The second magnetism-shielding member 240 is made of a material having high magnetic permeability and small coercive force. The member 240 is made of, for example, PB permalloy or PC permalloy, which is a nickel-iron alloy containing 35 to 80% nickel.

The second substrate 68 covered with the second magnetism-shielding member 240 is held in the second substrate storage case 230. The second substrate storage case 230 is made of a non-magnetic material. The second substrate storage case 230 opens at the distal end. That is, its distal end opens, in the first direction A, to the second holding groove 70. Thus, the second substrate storage case 230 does not prevent the wire rope W from being held in the second holding groove 70.

FIGS. 2 and 3 illustrate neither the second magnetism-shielding member 240 nor the second substrate storage case 230, thereby showing the second substrate 68 and second magnetic-flux detecting elements 75 to 80 more conspicuously than otherwise.

The second magnetic-flux detecting elements 75 to 80 have the same positional relation to the second holding groove 70 as the first magnetic-flux detecting elements 45 to 50 have to the first holding groove 40. This structural point will be described below in detail.

In the embodiment, the first holding groove 40 and the second holding groove 70 have the same shape. As described above, the second magnetic-flux detecting elements 75 to 80 have the same positional relation to the second holding groove 70 as the positional relation the first magnetic-flux detecting elements 45 to 50 have to the first holding groove 40. Hence, if the first holding groove 40 overlaps the second holding groove 70, or if the edges of the first holding groove 40 are aligned with those of the second holding groove 70, the first magnetic-flux detecting element 45 will overlap the second magnetic-flux detecting element 75, the first magnetic-flux detecting element 46 will overlap the second magnetic-flux detecting element 76, the first magnetic-flux detecting element 47 will overlap the second magnetic-flux detecting element 77, the first magnetic-flux detecting element 48 will overlap the second magnetic-flux detecting element 78, the first magnetic-flux detecting element 49 will overlap the second magnetic-flux detecting element 79, and the first magnetic-flux detecting element 50 will overlap the second magnetic-flux detecting element 80.

Hence, while the case 21 remains closed as shown in FIG. 2, a gap is provided, defined by the first and second holding grooves 40 and 70 as viewed in the first direction A, and the wire rope W is held in the gap. Across the center of this gap, the first and second magnetic-flux detecting elements 45 and 75 are diagonally opposed, the first and second detecting elements 46 and 76 are orthogonally opposed, the first and second detecting elements 47 and 77 are orthogonally opposed, first and second detecting elements 48 and 78 are orthogonally opposed, the first magnetic-flux detecting element 49 and second detecting element 79 are orthogonally opposed, and the first magnetic-flux detecting element 50 and second detecting element 80 are orthogonally opposed.

As may be seen from FIG. 1, the result of detection performed by the second magnetic-flux detecting elements 75 to 80 is transmitted to the signal processing device 100.

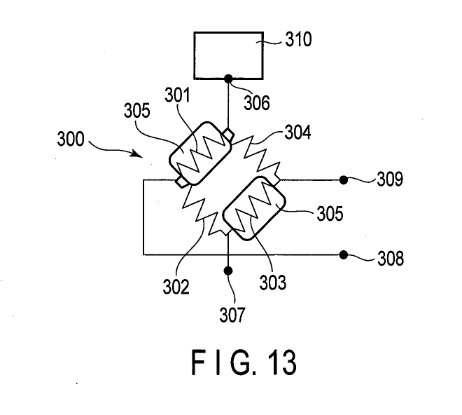

The GMR elements used as first and second magnetic-flux detecting elements will be described in detail. FIG. 13 is an equivalent circuit diagram illustrating the internal configuration of each GMR element. As shown in FIG. 13, the GMR element comprises first to fourth magnetoresistive elements 301 to 304. The four magnetoresistive elements 301 to 304 constitute a bridge circuit 300, which can generate a differential output. The first to fourth magnetoresistive elements 301 to 304 are electrically connected, one to another in the order mentioned, forming a ring. The first and third magnetoresistive elements 301 and 303, opposing each other, are covered with a magnetism-shielding member 305 and are magnetically shielded.

The bridge circuit 300 comprises a power input terminal 306, a ground terminal 307, a first output terminal 308, and a second output terminal 309. The power input terminal 306 is electrically connected to the node of the first and fourth magnetoresistive elements 301 and 304. To the power input terminal 306, a voltage is applied from a power supply 310. The power supply 310 supplies power to the first magnetic-flux detecting elements 45 to 50 and the second magnetic-flux detecting elements 75 to 80. The power supply 310 is arranged, for example, outside the case 21.

The ground terminal 307 is electrically connected to the node of the second and third magnetoresistive elements 302 and 303. The first output terminal 308 is electrically connected to the node of the first and second magnetoresistive elements 301 and 302. The second output terminal 309 is electrically connected to the node of the third and fourth magnetoresistive elements 303 and 304. The first and second output terminal 308 and 309 transmit signals to the signal processing device 100, which will be described later.

As shown in FIG. 4, the second guard member 64 is secured to the second case member 23, held in the second holding groove 70 and faces the second bottom surface 71. The second guard member 64 is fastened by fastening members 301 to, for example, a second substrate-supporting part 84. The second guard member 64 is shaped like a rod, and is long in the first direction A, covering both second magnet members 69. The second guard member 64 prevents the wire rope W from directly contacting the second magnet members 69 and inner surface of the first holding groove 70 when wire rope W is placed in the second holding groove 70. To be more specific, the wire rope W contacts the second guard member 64, and never directly contacts the second magnet members 69 and the inner surface of the second holding groove 70.

The positional relation the first substrate 38 and the second substrate 68 have relative to each other will be described. As shown in FIG. 4, the first substrate 38 and the second substrate 68 are spaced apart from each other in the first direction A. However, the first and second substrates 38 and 68 are so arranged that the first and second holding grooves 40 and 70 overlap as shown in FIG. 2, as they are viewed in the first direction A. More precisely, the first and second bottom wall parts 24 and 26 are so arranged that they appear to be overlapping in the second direction B as shown in FIG. 2, as viewed in the first direction A. Hence, the wire rope W can be held in the first second holding grooves 40 and 70.

The position adjusting device 65 can adjust a position of the second substrate 68 with respect to the second bottom wall part 26 in the second direction B. The position adjusting device 65 comprises a second yoke 66, a first step part 80a, a second step part 80b, a bolt 82, a nut 83, a second substrate supporting part 84, and first and second coil springs 85 and 86.

In the embodiment, the second yoke 66 functions as a part of the position adjusting device 65. Two projections 87 are provided at the ends of the second yoke 66, respectively, both protruding in the first direction A. The step parts are formed, one between the bottom surface 66b of the second yoke 66 and the bottom surface 87a of one projection 87, and the other between the bottom surface 66b and the bottom surface 87a of the other projection 87. One of the projections 87 has a through hole 87b.

The first step part 80a is secured to the second case member 23. In the embodiment, it is secured to, for example, the second bottom wall part 26 of the second substrate 68. The first step part 80a comprises first to third steps 90 to 92, as an example of structure which comprises some steps which are arranged in the second direction B. The first to third steps 90 to 92 differ in height measured from the second bottom wall part 26 in the second direction B.

The first step 90 is the lowest step, having a first flat part 90a perpendicular to the second direction B. The second step 91 is a step which is higher than the first step 90. The second step 91 has a second flat part 91a perpendicular to the second direction B. The third step 92 is the highest step, having a third flat part 92a perpendicular to the second direction B.

The distance between the first and second flat parts 90a and 91a, measured in the second direction B, is equal to the distance between the second and third flat parts 91a and 92a, which is measured in the second direction B. Namely, both distances are L1. Further, the distance between the inner surface 26b of the second bottom wall part 26 and the first and second flat part 90a, measured in the second direction B, is also L1. The distance between the bottom surface 67a of the second yoke 66 and the bottom surface 87a of the projection 87, measured in the second direction B, may be L1 or less, and is, for example, L1 in the embodiment.

The first step part 80a has first to third through holes 93 to 95. The first through hole 93 penetrates the first step 90 and extends in the second direction B. The second through hole 94 extends in the second direction B, passing through the second step 91. The third through hole 95 extends in the second direction B, passing through the third step 92. The second bottom wall part 26 has through holes 26a, which align with the first to third through holes 93 to 95, respectively.

The second step part 80b has the same shape as the first step part 80a. The parts of the second step part 80b which are identical in function to those of the first step part 80a are designated by the same reference numbers and will not be described. The second step part 80b may not have first to third through holes 93 to 95.

The second step part 80b is spaced from the first step part 80a in the first direction A and assumes a posture inverse to that of the first step part 80a. The second step part 80b is supported on the second bottom wall part 26 by a sliding mechanism 96 and can slide in the first direction A.

The second yoke 66 is secured to the second bottom wall part 26 via the first and second step parts 80a and 80b. More precisely, one of the projections 87 of the second yoke 66 is mounted on one of the flat parts of the first step part 80a, and the other projection 87 of the second yoke 66 is mounted on the same flat part of the second step part 80b.

The bolt 82 mentioned above is inserted, passing through the hole made in the step part of the first step part 80a on which the projection 87 putted, and also through the hole 26a made in the second bottom wall part 26 and aligned with the hole made in that part of the first step part 80a. The nut 83 mentioned above is mounted in screw engagement with the bolt 82 and turned. Thus, the bolt 82 and nut 83 thereby fasten the second yoke 66 to the second bottom wall part 26.

The second substrate supporting part 84 is positioned at the first part with respect to the second yoke 66. The second substrate supporting part 84 is supported on the second yoke 66 by the first and second coil springs 85 and 86.

The first coil spring 85 is arranged at one end of the second yoke 66 as viewed in the first direction A and positioned at one side of a second magnet member 69, facing the other second magnet member 69. The second coil spring 86 is arranged at the other end of the second yoke 66, and is positioned at one side of the other second magnet member 69, facing the first-mentioned second magnet member 69.

The first and second coil springs 85 and 86 have a length, providing a first gap S1 between the second substrate supporting part 84 and the second magnet members 69. The first gap S1 is the distance L1 over which the first and second coil springs 85 and 86 may be compressed in the second direction B. In other words, the gap S1 is equal to the distance between the flat surfaces of the first and second step parts 80a and 80b, measured in the second direction B.

The second substrate supporting part 84 has a recess 97 located between the first and second coil springs 85 and 86. The recess 97 recedes toward the second yoke 66. The second substrate 68 is secured above the recess 97. A second gap 2S is provided between the recess 97 and the second yoke 66. The second gap S2 is the distance L1 measured in the second direction B.

Thus, the first gap S1 is provided between the second substrate supporting part 84 and the second magnet members 69, and the second gap S2 is provided between the second substrate supporting part 84 and the second yoke 66. The first and second coil springs 85 and 86 can therefore be compressed over the distance L1 in the second direction B. Hence, the second substrate supporting part 84 can move by distance L1 because of the first and second coil springs 85 and 86. When released from any external force, the second substrate supporting part 84 is moved back to the initial position by the first and second coil springs 85 and 86.

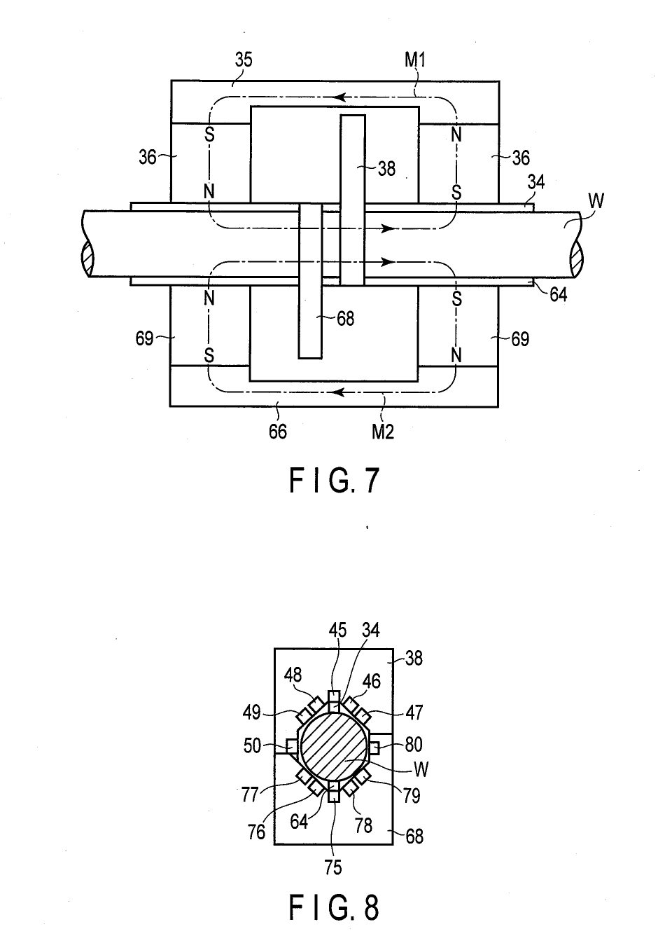

FIG. 7 is a schematic diagram showing the wire rope W held in the first and second holding grooves 40 and 70, while the case 21 remains closed. To hold the wire rope W in the first and second holding grooves 40 and 70, the operator first grips and pulls the handle 200, opening the case 21. Then, the operator places the wire rope W in the second holding groove 70. Next, the operator grips and pushes the handle 200, closing the case 21. The wire rope W is thereby held in the space defined by the first and second holding grooves 40 and 70.

Once the wire rope W has been held in the first and second holding grooves 40 and 70 as shown in FIG. 7, the first magnet members 36 face the wire rope W, generating a magnetic flux M1 in the wire rope W. Similarly, the second magnet members 69 face the wire rope W, generating a magnetic flux M2 in the wire rope W. The magnetic flux M2 extends in the same direction as the magnetic flux M1.

FIG. 8 is a schematic diagram showing the first and second substrates 38 and 68 as viewed in the first direction A, and showing the wire rope W held in the first and second holding grooves 40 and 70. As shown in FIG. 8, the first magnetic-flux detecting elements 45 to 50 are positioned to oppose a first part 30, which is a half circumferential surface of the wire rope W in the first part 30 side. The second magnetic-flux detecting elements 75 to 80 are positioned to oppose the other second part 60, which is the other half circumferential surface of the wire rope W. Thus, the first magnetic-flux detecting elements 45 to 50 and the second magnetic-flux detecting elements 75 to 80 surround the circumferential surface of the wire rope W.

If the wire rope W is damaged at a part, a magnetic flux leaks at the damaged part of the wire rope W. The magnetic flux leaking from the damaged part is detected by one of the first magnetic-flux detecting elements 45 to 50 or one of the second magnetic-flux detecting elements 75 to 80. This is because the first detecting elements 45 to 50 and second magnetic-flux detecting elements 75 to 80 surround the circumferential surface of the wire rope W.

The wire rope W is moved in its extending direction, relative to the wire-rope damage detecting apparatus 20. The apparatus 20 can therefore detect magnetic fluxes leaking from any parts of the wire rope W.

The detecting results of the first magnetic-flux detecting elements 45 to 50 and the detecting results of the second magnetic-flux detecting elements 75 to 80 are transmitted to the signal processing device 100.

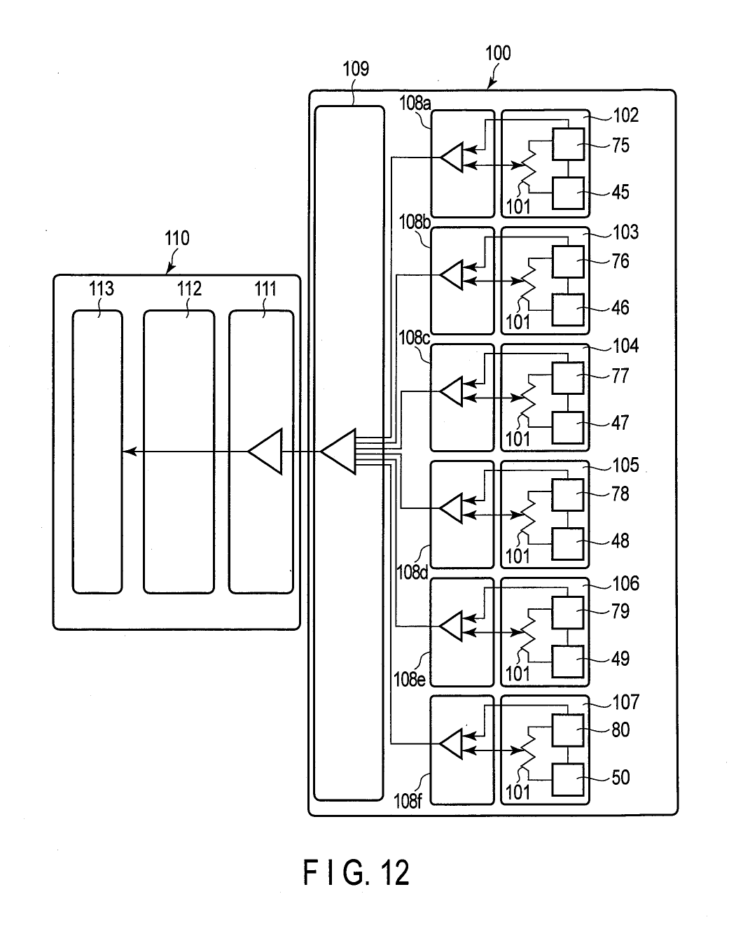

FIG. 12 is a block diagram showing the signal processing device 100 and the alarm device 110. As shown in FIG. 12, the signal processing device 100 comprises a plurality of detection-sensitivity balancing circuits, a plurality of differential amplifying circuits, and a waveform synthesizing circuit 109.

Each detection-sensitivity balancing circuit comprises a first magnetic-flux detecting element (i.e., one of elements 45 to 50), a second magnetic-flux detecting element (i.e., one of elements 75 to 80), and an adjusting resistor element 101.

Each detection-sensitivity balancing circuit has the function of adjusting the outputs of the first and second magnetic-flux detecting elements to the values they should have if the first and second magnetic-flux detecting elements detect magnetic fluxes of the same intensity.

In the embodiment, two magnetic-flux detecting elements are combined, which diagonally oppose each other once the case 21 has been closed. Therefore, the signal processing device 100 has six detection-sensitivity balancing circuits. The six detection-sensitivity balancing circuits will be described in detail. In this embodiment, as the six detection-sensitivity balancing circuits, first to six detection-sensitivity balancing circuits 102 to 107 are provided.

The first detection-sensitivity balancing circuit 102 comprises a first magnetic-flux detecting element 45, a second magnetic-flux detecting element 75, and an adjusting resistor element 101. The first and second magnetic-flux detecting elements 45 and 75 are electrically connected to each other by a connection line, and also by the adjusting resistor element 101. In the first detection-sensitivity balancing circuit 102, the sensitivity is adjusted, with which the first and second magnetic-flux detecting elements 45 and 75 detect any magnetic flux leaking from the wire rope W.

More specifically, the first output terminal 308 of the first magnetic-flux detecting element 45 is electrically connected to the second output terminal 308 of the second magnetic-flux detecting element 75. The second output terminal 309 of the first magnetic-flux detecting element 45 is electrically connected to one end of the adjusting resistor element 101. The second output terminal 309 of the second magnetic-flux detecting element 75 is electrically connected to the other end of the adjusting resistor element 101.

The adjusting resistor element 101 of the first detection-sensitivity balancing circuits 102 has such a resistance value that the output difference between the first and second magnetic-flux detecting elements 45 and 75 is zero when they detect magnetic fluxes of the same intensity.

The adjusting resistor element 101 outputs the sum of the signal values of the first and second magnetic-flux detecting elements 45 and 75, the sum having been obtained at the second output terminal 309. The adjusting resistor element 101 also outputs the sum of the signal values of the first and second magnetic-flux detecting elements 45 and 75, the sum having been obtained at the first output terminal 308.

The second detection-sensitivity balancing circuit 103 comprises a first magnetic-flux detecting element 46, a second magnetic-flux detecting element 76, and an adjusting resistor element 101. The first and second magnetic-flux detecting elements 46 and 76 are electrically connected to each other by a connection line, and also by the adjusting resistor element 101. In the second detection-sensitivity balancing circuit 103, the sensitivity is adjusted, with which the first and second magnetic-flux detecting elements 46 and 76 detect any magnetic flux leaking from the wire rope W.

More specifically, the first output terminal 308 of the first magnetic-flux detecting element 46 is electrically connected to the second output terminal 308 of the second magnetic-flux detecting element 76. The second output terminal 309 of the first magnetic-flux detecting element 46 is electrically connected to one end of the adjusting resistor element 101. The second output terminal 309 of the second magnetic-flux detecting element 76 is electrically connected to the other end of the adjusting resistor element 101.

The adjusting resistor element 101 of the second detection-sensitivity balancing circuits 103 has such a resistance value that the output difference between the first and second magnetic-flux detecting elements 46 and 76 is zero when they detect magnetic fluxes of the same intensity.

The adjusting resistor element 101 outputs the sum of the signal values of the first and second magnetic-flux detecting elements 46 and 76, the sum having been obtained at the second output terminal 309. The adjusting resistor element 101 also outputs the sum of the signal values of the first and second magnetic-flux detecting elements 46 and 76, the sum having been obtained at the first output terminal 308.

The third detection-sensitivity balancing circuit 104 comprises a first magnetic-flux detecting element 47, a second magnetic-flux detecting element 77, and an adjusting resistor element 101. The first and second magnetic-flux detecting elements 47 and 77 are electrically connected to each other by a connection line, and also by the adjusting resistor element 101. In the third detection-sensitivity balancing circuit 104, the sensitivity is adjusted, with which the first and second magnetic-flux detecting elements 47 and 77 detect any magnetic flux leaking from the wire rope W.

More specifically, the first output terminal 308 of the first magnetic-flux detecting element 47 is electrically connected to the second output terminal 308 of the second magnetic-flux detecting element 77. The second output terminal 309 of the first magnetic-flux detecting element 47 is electrically connected to one end of the adjusting resistor element 101. The second output terminal 309 of the second magnetic-flux detecting element 77 is electrically connected to the other end of the adjusting resistor element 101.

The adjusting resistor element 101 of the third detection-sensitivity balancing circuits 104 has such a resistance value that the output difference between the first and second magnetic-flux detecting elements 47 and 77 is zero when they detect magnetic fluxes of the same intensity.

The adjusting resistor element 101 outputs the sum of the signal values of the first and second magnetic-flux detecting elements 47 and 77. The sum has been obtained at the second output terminal 309. The adjusting resistor element 101 also outputs the sum of the signal values of the first and second magnetic-flux detecting elements 47 and 77, the sum having been obtained at the first output terminal 308.

The fourth detection-sensitivity balancing circuit 105 comprises a first magnetic-flux detecting element 48, a second magnetic-flux detecting element 78, and an adjusting resistor element 101. The first and second magnetic-flux detecting elements 48 and 78 are electrically connected to each other by a connection line, and also by the adjusting resistor element 101. In the fourth detection-sensitivity balancing circuit 105, the sensitivity is adjusted, with which the first and second magnetic-flux detecting elements 48 and 78 detect any magnetic flux leaking from the wire rope W.

More specifically, the first output terminal 308 of the first magnetic-flux detecting element 48 is electrically connected to the second output terminal 308 of the second magnetic-flux detecting element 78. The second output terminal 309 of the first magnetic-flux detecting element 48 is electrically connected to one end of the adjusting resistor element 101. The second output terminal 309 of the second magnetic-flux detecting element 78 is electrically connected to the other end of the adjusting resistor element 101.

The adjusting resistor element 101 of the fourth detection-sensitivity balancing circuits 105 has such a resistance value that the output difference between the first and second magnetic-flux detecting elements 48 and 78 is zero when they detect magnetic fluxes of the same intensity.

The adjusting resistor element 101 outputs the sum of the signal values of the first and second magnetic-flux detecting elements 48 and 78, the sum having been obtained at the second output terminal 309. The adjusting resistor element 101 also outputs the sum of the signal values of the first and second magnetic-flux detecting elements 48 and 78, the sum having been obtained at the first output terminal 308.

The fifth detection-sensitivity balancing circuit 106 comprises a first magnetic-flux detecting element 49, a second magnetic-flux detecting element 79, and an adjusting resistor element 101. The first and second magnetic-flux detecting elements 49 and 79 are electrically connected to each other by a connection line, and also by the adjusting resistor element 101. In the fifth detection-sensitivity balancing circuit 106, the sensitivity is adjusted, with which the first and second magnetic-flux detecting elements 49 and 79 detect any magnetic flux leaking from the wire rope W.

More specifically, the first output terminal 308 of the first magnetic-flux detecting element 49 is electrically connected to the second output terminal 308 of the second magnetic-flux detecting element 79. The second output terminal 309 of the first magnetic-flux detecting element 49 is electrically connected to one end of the adjusting resistor element 101. The second output terminal 309 of the second magnetic-flux detecting element 79 is electrically connected to the other end of the adjusting resistor element 101.

The adjusting resistor element 101 of the fifth detection-sensitivity balancing circuits 106 has such a resistance value that the output difference between the first and second magnetic-flux detecting elements 49 and 79 is zero when they detect magnetic fluxes of the same intensity.

The adjusting resistor element 101 outputs the sum of the signal values of the first and second magnetic-flux detecting elements 49 and 79. This sum has been obtained at the second output terminal 309. The adjusting resistor element 101 also outputs the sum of the signal values of the first and second magnetic-flux detecting elements 49 and 79, the sum having been obtained at the first output terminal 308.

The sixth detection-sensitivity balancing circuit 107 comprises a first magnetic-flux detecting element 50, a second magnetic-flux detecting element 80, and an adjusting resistor element 101. The first and second magnetic-flux detecting elements 50 and 80 are electrically connected to each other by a connection line, and also by the adjusting resistor element 101. In the sixth detection-sensitivity balancing circuit 107, the sensitivity is adjusted, with which the first and second magnetic-flux detecting elements 50 and 80 detect any magnetic flux leaking from the wire rope W.

More specifically, the first output terminal 308 of the first magnetic-flux detecting element 50 is electrically connected to the second output terminal 308 of the second magnetic-flux detecting element 80. The second output terminal 309 of the first magnetic-flux detecting element 50 is electrically connected to one end of the adjusting resistor element 101. The second output terminal 309 of the second magnetic-flux detecting element 80 is electrically connected to the other end of the adjusting resistor element 101.

The adjusting resistor element 101 of the sixth detection-sensitivity balancing circuits 107 has such a resistance value that the output difference between the first and second magnetic-flux detecting elements 50 and 80 is zero when they detect magnetic fluxes of the same intensity.

The adjusting resistor element 101 outputs the sum of the signal values of the first and second magnetic-flux detecting elements 50 and 80, the sum having been obtained at the second output terminal 309. The adjusting resistor element 101 also outputs the sum of the signal values of the first and second magnetic-flux detecting elements 50 and 80, the sum having been obtained at the first output terminal 308.

In the embodiment described above, a first magnetic-flux detecting element and a second magnetic-flux detecting element, which are positioned diagonally to each other while the case 21 remains closed, constitute one combination. Alternatively, a first magnetic-flux detecting element and a second magnetic-flux detecting element, which oppose each other while the case 21 remains closed, may constitute one combination. In this case, the magnetic-flux detecting elements 45 and 75 constitute a combination, the magnetic-flux detecting elements 48 and 76 constitute combination; the magnetic-flux detecting elements 49 and 77 constitute combination, the magnetic-flux detecting elements 46 and 78, the magnetic-flux detecting elements 47 and 79, and the magnetic-flux detecting elements 50 and 80.

The differential amplifying circuits are provided, each for one detection-sensitivity balancing circuit. Each differential amplifying circuit amplifies the outputs of the first and second magnetic-flux detecting elements with an amplification factor, keeping constant difference in magnetic-flux sensitivity between the first and second magnetic-flux detecting elements. The amplification factor is variable. Since the amplification factor is variable, the amplification factors of the respective differential amplifying circuits can be adjusted individually. The signals output from the differential amplifying circuits can therefore have the same magnitude.

The embodiment comprises first to sixth differential amplifying circuits 108a to 108f. The first differential amplifying circuit 108a is provided for the first detection-sensitivity balancing circuit 102.

The first differential amplifying circuit 108a is electrically connected to the adjusting resistor element 101 and the second magnetic-flux detecting element 75. The first differential amplifying circuit 108a amplifies the differential outputs of the first and second magnetic-flux detecting elements 45 and 75 with a preset amplification factor, keeping constant difference in magnetic-flux sensitivity of the first and second magnetic-flux detecting elements 45 and 75. The amplification factor has been set so that the first to sixth differential amplifying circuits 108a to 108f may generate signals of the same magnitude.

More specifically, the first differential amplifying circuit 108a calculates the difference between the sum of the outputs coming from the second output terminals 309 of the first and second magnetic-flux detecting elements 45 and 75 and the sum of the outputs coming from the first output terminals 308 of the first and second magnetic-flux detecting elements 45 and 75. These sums have passed through the adjusting resistor element 101. Then, the first differential amplifying circuit 108a amplifies the difference so calculated, by the preset amplification factor, and outputs the difference so amplified.

The second differential amplifying circuit 108b is provided for the second detection-sensitivity balancing circuits 103. The second differential amplifying circuit 108b is electrically connected to the adjusting resistor element 101 and the second magnetic-flux detecting element 76. The second differential amplifying circuit 108b amplifies the differential outputs of the first and second magnetic-flux detecting elements 46 and 76 with a preset amplification factor, keeping constant difference in magnetic-flux sensitivity between the first and second magnetic-flux detecting elements 46 and 76, thereby generating signal amplified to the same magnitude.

More specifically, the second differential amplifying circuit 108b calculates the difference between the sum of the outputs coming from the second output terminals 309 of the first and second magnetic-flux detecting elements 46 and 76 and the sum of the outputs coming from the first output terminals 308 of the first and second magnetic-flux detecting elements 46 and 76. These sums have passed through the adjusting resistor element 101. Then, the second differential amplifying circuit 108b amplifies the difference so calculated, by the preset amplification factor, and outputs the difference so amplified.

The third differential amplifying circuit 108c is provided for the third detection-sensitivity balancing circuits 104. The third differential amplifying circuit 108c is electrically connected to the adjusting resistor element 101 and the second magnetic-flux detecting element 77. The third differential amplifying circuit 108c amplifies the differential outputs of the first and second magnetic-flux detecting elements 47 and 77 with a preset amplification factor, keeping constant difference in magnetic-flux sensitivity of the first and second magnetic-flux detecting elements 44 and 77, thereby generating signal amplified to the same magnitude.

More specifically, the third differential amplifying circuit 108c calculates the difference between the sum of the outputs coming from the second output terminals 309 of the first and second magnetic-flux detecting elements 47 and 77 and the sum of the outputs coming from the first output terminals 308 of the first and second magnetic-flux detecting elements 47 and 77. These sums have passed through the adjusting resistor element 101. Then, the third differential amplifying circuit 108c amplifies the difference so calculated, by the preset amplification factor, and outputs the difference so amplified.

The fourth differential amplifying circuit 108d is provided for the fourth detection-sensitivity balancing circuits 105. The fourth differential amplifying circuit 108d is electrically connected to the adjusting resistor element 101 and the second magnetic-flux detecting element 78. The fourth differential amplifying circuit 108d amplifies the differential outputs of the first and second magnetic-flux detecting elements 48 and 78 with a preset amplification factor, keeping constant difference in magnetic-flux sensitivity between the first and second magnetic-flux detecting elements 48 and 78, thereby generating signal amplified to the same magnitude.

More specifically, the fourth differential amplifying circuit 108d calculates the difference between the sum of the outputs coming from the second output terminals 309 of the first and second magnetic-flux detecting elements 48 and 78 and the sum of the outputs coming from the first output terminals 308 of the first and second magnetic-flux detecting elements 48 and 78. These sums have passed through the adjusting resistor element 101. Then, the fourth differential amplifying circuit 108d amplifies the difference so calculated, by the preset amplification factor, and outputs the difference so amplified.

The fifth differential amplifying circuit 108e is provided for the fifth detection-sensitivity balancing circuits 106. The fifth differential amplifying circuit 108e is electrically connected to the adjusting resistor element 101 and the second magnetic-flux detecting element 79. The fifth differential amplifying circuit 108e amplifies the differential outputs of the first and second magnetic-flux detecting elements 49 and 79 with a preset amplification factor, keeping constant difference in magnetic-flux sensitivity between the first and second magnetic-flux detecting elements 49 and 79, thereby generating signal amplified to the same magnitude.

More specifically, the fifth differential amplifying circuit 108e calculates the difference between the sum of the outputs coming from the second output terminals 309 of the first and second magnetic-flux detecting elements 49 and 79 and the sum of the outputs coming from the first output terminals 308 of the first and second magnetic-flux detecting elements 45 and 75. These sums have passed through the adjusting resistor element 101. Then, the fifth differential amplifying circuit 108e amplifies the difference so calculated, by the preset amplification factor, and outputs the difference so amplified.

The sixth differential amplifying circuit 108f is provided for the sixth detection-sensitivity balancing circuits 107. The sixth differential amplifying circuit 108f is electrically connected to the adjusting resistor element 101 and the second magnetic-flux detecting element 80. The sixth differential amplifying circuit 108f amplifies the differential outputs of the first and second magnetic-flux detecting elements 50 and 80 with a preset amplification factor, keeping constant difference in magnetic-flux sensitivity between the first and second magnetic-flux detecting elements 50 and 80, thereby generating signal amplified to the same magnitude.

More specifically, the sixth differential amplifying circuit 108f calculates the difference between the sum of the outputs coming from the second output terminals 309 of the first and second magnetic-flux detecting elements 50 and 80 and the sum of the outputs coming from the first output terminals 308 of the first and second magnetic-flux detecting elements 50 and 80. These sums have passed through the adjusting resistor element 101. Then, the sixth differential amplifying circuit 108f amplifies the difference so calculated, by the preset amplification factor, and outputs the difference so amplified.

The waveform synthesizing circuit 109 synthesizes the signals output from the first to sixth differential amplifying circuits 108a to 108f.

The alarm device 110 comprises a waveform shaping circuit 111, a damage determining circuit 112, and an alarm unit 113. The waveform shaping circuit 111 receives a waveform signal representing the waveform from the waveform synthesizing circuit 109 of the signal processing device 100.

The waveform shaping circuit 111 has the function of rectifying the waveform of the signal output from the waveform synthesizing circuit 109 so that the signal may be easily used in the damage determining circuit 112. In the embodiment, the waveform shaping circuit 111 performs, for example, an absolute-value process on the signal synthesized in the waveform synthesizing circuit 109. In the absolute-value process, the negative-side waveform part of the signal synthesized in the waveform synthesizing circuit 109 is added to the positive-side waveform part of the signal. Instead, an offset process may be performed in the waveform shaping circuit 111. In the offset process, the signal is offset to the positive side so that the waveform of the synthesized in the waveform synthesizing circuit 109 may be shifted to the positive side.

The embodiment uses the waveform shaping circuit 111, and the signal synthesized in the waveform synthesizing circuit 109 is easily used in the damage determining circuit 112. The waveform shaping circuit 111 may not be used, nonetheless. In this case, the signal synthesized in the waveform synthesizing circuit 109 is transmitted directly to the damage determining circuit 112, and the damage determining circuit 112 uses the signal to perform its function.

The damage determining circuit 112 receives a signal from the waveform shaping circuit 111. From the signal it has received, the damage determining circuit 112 determines a damaged part, if any, of the wire rope W. To notify the surroundings of the detected damaged part, the damage determining circuit 112 transmits a signal to the alarm unit 113. On the basis of the signal, the alarm unit 113 informs of the damage part of the wire rope W. The alarm unit 113 may display, for example, the image of the damage part.

The position adjusting device 65 can place the wire rope W in the first and second holding grooves 40 and 70, in contact with the first and second guard members 34 and 64, regardless of the diameter of the wire rope W. That is, the wire rope W can be held in the first and second holding grooves 40 and 70, with the distance from the wire rope W to the first magnetic-flux detecting elements 45 to 50 and the distance from the wire rope W to the second magnetic-flux detecting elements 75 to 80 remaining minimal.

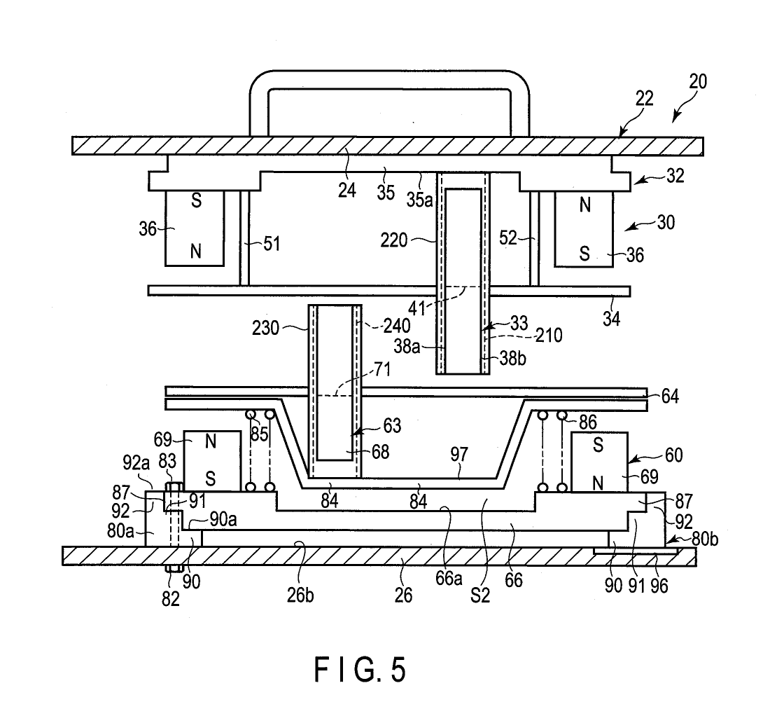

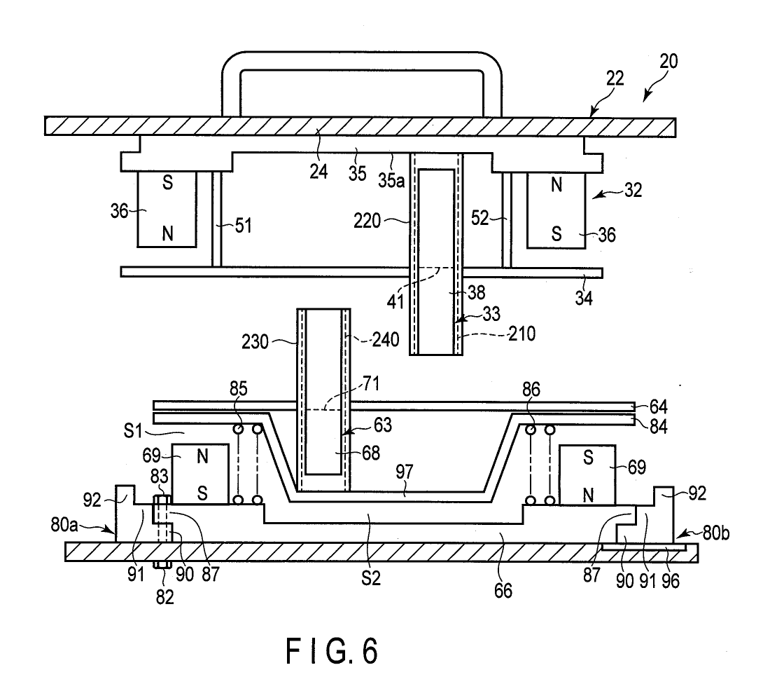

How the position adjusting device 65 operates will be explained. FIG. 5 is, like FIG. 4, a schematic diagram showing the wire-rope damage detecting apparatus 20. As shown in FIG. 5, the second yoke 66 is secured to the second flat parts 91a of the second steps 91 of the first and second step parts 80a and 80b. FIG. 6 shows the second yoke 66 secured on the flat parts 90a of the first steps 90 of the first and second step parts 80a and 80b. The distance between the bottom surface 66b of the second yoke 66 and the bottom surface 87a of the projection 87, measured in the second direction B, is equal to or shorter than the distance L1. The bottom surfaces 87a of the projections 87 can therefore be mounted stably on the flat parts 90a. As shown in FIGS. 5 and 6, the sliding mechanism adjusts the position of the second step part 80b in the first direction A, in order to mount the bottom surface 67a of the other projection 87 on the flat part of each step of the second step part 80b.

FIGS. 8 to 11 are schematic diagrams showing the positions the first and second substrates 38 and 68 have relative to each other, while the wire rope W remains held in the first and second holding grooves 40 and 70. As shown in FIGS. 5 and 6, the second yoke 66 may be changed in position with respect to the first and second step parts 80a and 80b. The distance between the first and second holding grooves 40 and 70 can be thereby changed in the second direction B.

Further, the second substrate 68 can be changed in position by distance L1 at most, in the second direction, by means of the first and second coil springs 85 and 86. Thus, if the wire rope W cannot be held firmly even when the first and second step parts 80a and 80b are adjusted, the first and second coil springs 85 and 86 are compressed and elastically deformed as the operator grips the handle 200 and pushes the first case member 22 onto the second case member 23, closing the case 21. Hence, the wire rope W can be held in the first and second holding grooves 40 and 70, while set in contact with the first and second guard members 34 and 64.

Moreover, the first and second substrates 38 and 68 have the first and second projecting parts 44 and 74, and the first and second magnetic-flux detecting elements 50 and 90 are secured to the first and second projecting parts 44 and 74. The wire rope W is therefore surrounded by the magnetic-flux detecting elements even if the first and second substrates 38 and 68 change in position relative to each other in accordance with the diameter of the wire rope W.

However, the distance between the first and second magnetic-flux detecting elements and the surface of the wire rope W changes in accordance with the diameter of the wire rope W. Hence, any magnetic-flux detecting element that is spaced apart from the wire rope W can be have its flux-detecting sensitivity adjusted.

The wire-rope damage detecting apparatus 20 configured as described above can detect any damaged part of the wire rope W, regardless of the diameter of the wire rope W, by using the position adjusting device 65.

Further, the apparatus 20 can detect damaged parts of wire ropes of various diameters, because it comprises the position adjusting device 65 that comprises the first and second step parts 80a and 80b for holding a wire rope and the first and second coil springs 85 and 86, i.e., elastic support members. Moreover, the second substrate 68 can be stabilized in posture, any damaged part of the wire rope W can be well detected, and the second magnet members 69 can be prevented from contacting the wire rope W, as will be described below in detail.

The first and second step parts 80a and 80b are combined with the first and second coil springs 85 and 86. This can reduce the positional change made by the first and second coils springs 85 and 86. More precisely, the positional change of the first and second coils springs 85 and 86, because of their elasticity, can be limited to the distance L1 between the steps adjacent to each other of the first step part 80a and the second step part 80b, never exceeding the distance.

If the positional change of the first and second coil springs 85 and 86 is increased, the second substrate 68 will be unstable in posture. However, since the positional change of the first and second coil springs 85 and 86 is decreased as described above, the second substrate 68 can be stable in posture.

To hold any one of wire ropes W having different diameters, the second yoke 66 may be supported by, for example, springs, instead of by the first and second step parts 80a and 80b. In this case, the area in which each first magnet member 36 opposes one second magnet member 69 across the wire rope W increases if the wire rope W has a small diameter. As a result, the first and second magnet members 36 and 69 repel each other with a magnetic force. As the first and second magnet member 36 and 69 repel each other, the springs supporting the second yoke 66 flex, moving the second magnet member 69 away from the wire rope W. Consequently, the magnetic flux M2 in the wire rope W becomes small, making it difficult to detect damaged parts of the wire rope W.

In the embodiment, however, the first and second step parts 80a and 80b hold the second magnet members 69 stepwise in the second direction B, at different heights. The second magnet members 69 will not move away from the wire rope W, and the magnetic flux M2 in the wire rope W will never become small. Any damaged part of the wire rope W can therefore be detected well.

If the wire rope W has a large diameter, the second magnet members 69 will be magnetically pulled toward the wire rope W. The second magnet members 69 are, however, prevented from contacting the wire rope W, because they are held in position by the first and second step parts 80a and 80b.

Since the first and second holding grooves 40 and 70 are V-shaped as viewed from above, the distances from the wire rope W to the first and second magnetic-flux detecting elements can remain short irrespective of the diameter of the wire rope W.

The GMR elements used as first and second magnetic-flux detecting elements can have their sensitivity adjusted. The output of any magnetic-flux detecting element that is spaced far from the wire rope W can therefore be adjusted and detect well any damaged part of the wire rope W.

More specifically, wire ropes W having different diameters may be held in the first and second holding grooves, one at a time, as shown in FIGS. 8 to 11. As a result, the magnetic-flux detecting elements arranged around the wire rope W change, and the distance between the wire rope W and any magnetic-flux detecting element arranged around the wire rope W changes, too. The longer the distance becomes, the smaller will be the output of the magnetic-flux detecting element.

In view of this, the amplification factors of the differential amplifying circuits, which are provided for the first and second magnetic-flux detecting elements arranged around the wire rope W, are increased, thereby to detect any damaged part well.

In the embodiment, the first and second magnetic-flux detecting elements are GMR elements, each being an example of an element the sensitivity of which can be adjusted. Instead, a plurality of anisotropic-magneto-resistive (AMR) elements may be used in this invention.

In the embodiment, the wire rope W is the object to inspect. Nonetheless, this invention can be applied to an apparatus for detecting damaged parts of any linear object other than a wire rope, such as a rod and a cord.

In the embodiment, the first and second magnetic-flux generating parts 32 and 62 are examples of the magnetic-flux generating unit used in this invention. The position adjusting device 65 is an example of the supporting unit in this invention. The first and second step parts 80a and 80b are examples of multi-step adjusting units used in this invention. The first and second coil springs 85 and 86 are examples of elastic supporting parts used in this invention.

The present invention is not limited to the embodiment described above. The components of the embodiment can be modified in various manners in reducing the invention to practice, without departing from the sprit or scope of the invention. Further, the components of the embodiment described above may be combined, if necessary, in various ways to make different inventions. For example, some of the components of the embodiment may not be used.

### EXPLANATION OF THE SYMBOLS

What is claimed is:

1. A damage detecting apparatus comprising:
a magnetic-flux generating unit configured to generate a magnetic flux in an object to be inspected, the object having magnetic flux;
a first magnetic-flux detecting element configured to detect a magnetic flux leaking from a circumferential part of the object;
a second magnetic-flux detecting element arranged, opposing the first magnetic-flux detecting element across the object, and configured to detect a magnetic flux leaking from any other circumferential part of the object; and
a supporting unit configured to support the first and second magnetic-flux detecting elements, enabling the first and second magnetic-flux detecting elements to change in position relative to each other in a diameter direction of the object.

2. The damage detecting apparatus according to claim 1, wherein the supporting means comprises:
a multi-step adjusting unit configured to change the first and second magnetic-flux detecting elements in position relative to each other in the diameter direction of the object; and
an elastic supporting part elastically supporting the second magnetic-flux detecting element, enabling the second magnetic-flux detecting element to move from the first magnetic-flux detecting element in the diameter direction of the object.

3. The damage detecting apparatus according to claim 1, further comprising:
a first substrate having a first holding groove configured to hold the object and secure the first magnetic-flux detecting element at an edge of the first holding groove; and
a second substrate having a second holding groove opposing the first holding groove and configured to hold the object and secure the second magnetic-flux detecting element at an edge of the second holding groove,
wherein the first and second holding grooves are V-shaped as viewed from above.

4. The damage detecting apparatus according to any one of claim 1, wherein:
the first magnetic-flux detecting element is provided in plurality, each having adjustable detection sensitivity; and
the second magnetic-flux detecting element is provided in plurality, each having adjustable detection sensitivity.

5. The damage detecting apparatus according to claim 4, wherein the first and second magnetic-flux detecting element are GMRs.

6. The damage detecting apparatus according to claim 4, wherein the first and second magnetic-flux detecting element are AMRs.

7. The damage detecting apparatus according to claim 1, wherein each of the magnetic-flux detecting elements is covered with a magnetism-shielding member.
